(19) United States
(12) Patent Application Publication
(10) Pub. No.: US 2016/0146856 A1
(43) Pub. Date: May 26, 2016

(54) Current Sensor

(71) Applicant: ROHM CO., LTD., Kyoto (JP)

(72) Inventors: Kunihiro Komiya, Kyoto (JP); Masahide Tanaka, Kyoto (JP)

(73) Assignee: ROHM Co., Ltd., Kyoto (JP)

(21) Appl. No.: 14/899,637

(22) PCT Filed: Jun. 11, 2014
(86) PCT No.: PCT/JP2014/065499

§ 371 Date: Dec. 18, 2015

(30) Foreign Application Priority Data
Jun. 21, 2013 (JP) 2013-130225

(51) Int. Cl. G01R 15/18; H02J 7/00; G01R 19/00

(52) U.S. Cl. CPC G01R 15/18; G01R 19/0092; H02J 7/007

(57) ABSTRACT

A current sensor has a measurement unit for measuring the current flowing through an electrical wire using electromagnetic induction caused by the magnetic flux around the electrical wire, a wireless transmission unit for wirelessly transmitting measurement results, a power generation unit for generating power using the same electromagnetic induction caused by the magnetic flux around the electrical wire, and a battery that is charged by the power generation unit and supplies power to the measurement unit and the wireless transmission unit. A sudden change in the current flowing through the electrical wire causes measurement to be carried out. The timing at which transmission is carried out is controlled according to the size of the current flowing through the electrical wire. When the measurement unit is measuring, power generation by the power generation unit is stopped. Measurement results obtained during insufficient charging are stored and sent after charge is secured.

### TECHNICAL FIELD

The present invention relates to a current sensor.

### BACKGROUND ART

For the purpose of providing a power measurement system and the like that need no special installation to be made by any skillful professionals, it has been proposed to provide a measurement apparatus and the like having a current sensor for detecting a waveform of current flowing through an electrical wire, in a noncontact manner, by means of electromagnetic inductive coupling and communication means (see Patent Literature 1 listed below).

### CITATION LIST

### Patent Literature

Patent Literature 1: Re-publication of PCT International Publication No. 2009-099082

### SUMMARY OF INVENTION

### Technical Problem

However, there are many problems to be further considered to achieve a more convenient current sensor.

In view of the above, an object of the present invention is to propose a more convenient current sensor.

### Solution to Problem

To achieve the above object, according to one aspect of the present invention, there is provided a current sensor including a measurement unit that measures current flowing through a target electrical wire that is a target of measurement, a wireless transmission unit that wirelessly transmits a result of measurement performed by the measurement unit, a power generation unit that generates power by means of electromagnetic induction caused by magnetic flux around the target electrical wire, and a storage battery that is charged by the power generation unit and supplies power to the measurement unit and the wireless transmission unit. This makes it possible for the measurement to be performed with supply of power from the current flowing through the target.

According to a specific feature of the present invention, the current sensor has a control unit that performs control such that the measurement unit performs measurement by means of change in the current flowing through a target electrical wire. This makes it possible for the measurement to be performed without missing any change in the current. According to more specific feature of the present invention, the control unit performs control such that the measurement unit performs measurement by means of a sudden change in the current flowing through the target electrical wire. According to further specific feature of the present invention, the control unit performs control such that the measurement unit performs measurement also at predetermined time intervals.

According to another specific feature of the present invention, the current sensor includes a control unit that controls, by means of magnitude of the current flowing through the target electrical wire, timing for the wireless transmission unit to perform transmission. This makes it possible to receive supply of power for measurement from the storage battery in a manner balanced with charging by the power generation unit.

According to another specific feature of the present invention, the current sensor has a control unit that makes the power generation unit stop power generation when the measurement unit performs measurement. This makes possible current measurement uninfluenced by the charging of the storage battery. According to another specific feature, the current sensor has a control unit that keeps the measurement unit from performing measurement when the control unit makes the power generation unit perform power generation.

According to another specific feature of the present invention, the current sensor has a storage unit in which the result of measurement performed by the measurement unit is stored, and also has a control unit that stores and maintains the result of measurement in the storage unit and makes the transmission unit transmit the result of measurement stored in the storage unit at timing different from timing of measurement. This makes it possible to perform more elaborate measurement. According to a more specific feature, the control unit stores and maintains the result of measurement in the storage unit when supply of power to the transmission unit from the storage battery is insufficient, and the control unit makes the transmission unit transmit the result of measurement stored in the storage unit when sufficient amount of power is securely supplied from the storage battery to the transmission unit.

According to another feature of the present invention, there is provided a current sensor that has a measurement unit that measures current flowing through a target electrical wire that is a target of measurement, a power generation unit that generates power by means of electromagnetic induction caused by magnetic flux around the target electrical wire, and a storage battery that is charged by the power generation unit and supplies power to the measurement unit. Here, the measurement unit is used both for measuring current flowing through a target electrical wire and for measuring current with which the storage battery is charged by the power generation unit. This makes it possible to perform current measurement and to confirm a secured state of power supply for the measurement.

According to another feature of the present invention, there is provided a current sensor having a measurement unit that measures current flowing through a target electrical wire by means of electromagnetic induction caused by magnetic flux around the target electrical wire, a power generation unit that generates power by means of electromagnetic induction caused by magnetic flux around the target electrical wire, and a storage battery that is charged by the power generation unit and supplies power to the measurement unit and the wireless transmission unit. Here, the measurement unit and the power generation unit share a common iron core. This makes it possible to measure current and secure power supply for the measurement with a simple configuration.

### Advantageous Effects of Invention

As has been discussed above, according to the present invention, there is provided a current sensor that is more convenient to use.

### BRIEF DESCRIPTION OF THE DRAWINGS

FIG. 1 is a system diagram illustrating an overall configuration of a first example of the present invention (Example 1);

FIG. 2 is partly a conceptual diagram and partly a block diagram of a current sensor in Example 1 illustrated in FIG. 1;

FIG. 3 is a flow chart illustrating an operation of a control unit of the current sensor in Example 1;

FIG. 4 is partly a conceptual diagram and partly a block diagram of a current sensor in a second example of the present invention (Example 2);

FIG. 5 is a flow chart illustrating an operation of a control unit of the current sensor in Example 2 illustrated in FIG. 4;

FIG. 6 is a flow chart illustrating an operation of a control unit of a current sensor in a third example of the present invention (Example 3);

FIG. 7 is a flow chart illustrating an operation of a control unit of a current sensor in a fourth example of the present invention (Example 4);

FIG. 8 is partly a conceptual diagram and partly a block diagram of a current sensor in a fifth example of the present invention (Example 5); and

FIGS. 9A, 9B, 9C, and 9D are each a diagram illustrating timing of an operation of a control unit in Example 5 illustrated in FIG. 8.

### DESCRIPTION OF EMBODIMENTS

### EXAMPLE 1

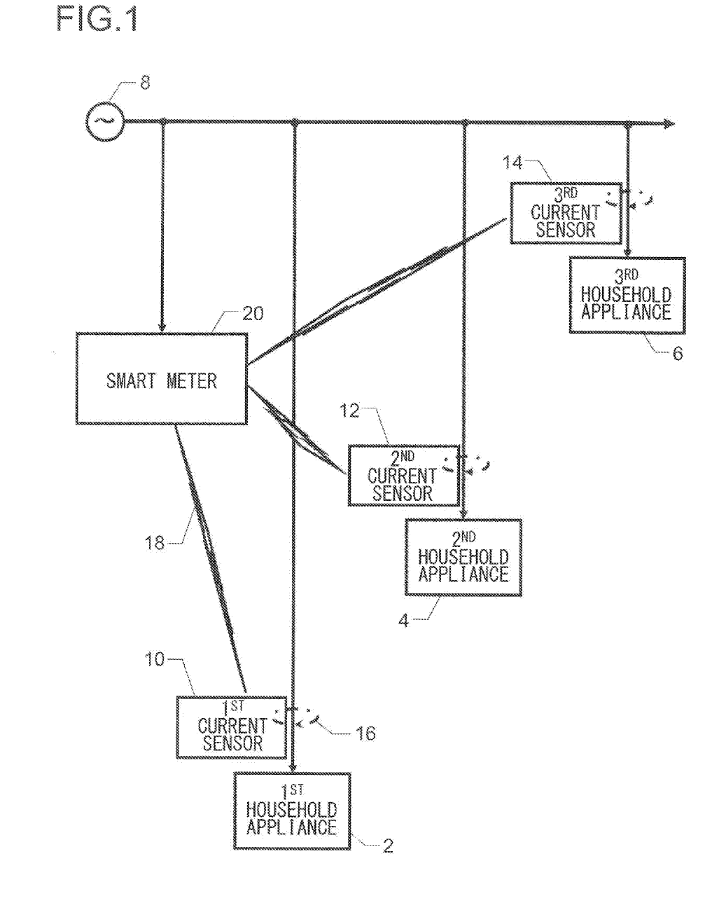

FIG. 1 is a system diagram illustrating an overall configuration of Example 1 where a current sensor according to an embodiment of the present invention is used. Example 1 constitutes a smart meter system in a house. In the house, there exist a first household appliance (e.g., a lighting appliance) 2, a second household appliance (e.g., a television set) 4, a third household appliance (e.g., a refrigerator) 6, etc. These household appliances are each connected to a commercial power supply 8 via a wall socket to receive power. Furthermore, there are also arranged a first current sensor 10, a second current sensor 12, and a third current sensor 14 corresponding to the first, second, and third household appliances, respectively. The first current sensor 10 detects density of magnetic flux around a cord through which power is supplied to the first household appliance 2, and thereby, the first current sensor 10 measures magnitude of current consumed by the first household appliance 2. The first current sensor 10 has short distance communication means, and transmits data of the measured current to a smart meter 20 by means of a radio wave 18. This operation also applies to the second and third current sensors 13 and 14.

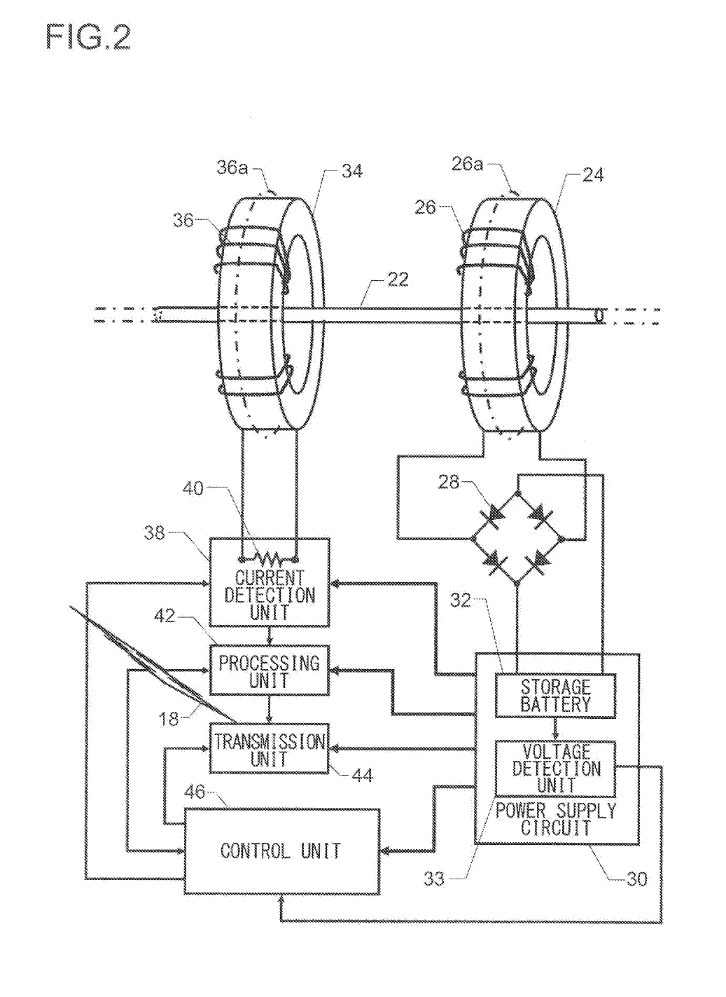

FIG. 2 is partly a conceptual diagram and partly a block diagram of a current sensor that is commonly used as the first current sensor 10, the second current sensor 12, and the third current sensor 14. A cord 22 is connected to the first household appliance 10, and around the cord 22, there is disposed an iron core ring 24 having a shape corresponding to magnetic flux that is generated around the cord 22. Around the iron core ring 24, a coil 26 is wound (the coil 26 is wound around unillustrated part of the iron-core ring 24, too, as indicated by an alternate dash and dot line 26a), and current extracted from an outgoing wire of the coil 26 charges a storage battery 32 in a power supply circuit 30 via a rectifier 28. The power supply circuit 30 includes a voltage detection unit 33 for checking a voltage to which the storage battery 32 is charged. As has been hitherto described, the power supply unit of the current sensor is configured to generate power by means of the current flowing through the cord 22 and accumulates the thus generated power therein.

Next, a description will be given of a configuration for receiving supply of power from the power supply circuit 30 and detecting current to transmit the detection result to the smart meter 20. Around the cord 22, there is disposed an iron core ring 34 configured in the same manner as the one for the power supply unit, and a coil 36 is wound around the iron core ring 34. An outgoing wire of the coil 36 is connected to a resistor 40 of a current detection unit 38, and the current detection unit 38 detects current flowing through the cord 22 as a voltage appearing across the resistor 40. Data of magnitude and variation of the current detected by the current detection unit 38 is processed by a processing unit 42, and is then transmitted from a transmission unit 44 to the smart meter 20. A control unit 46 controls the current detection performed by the current detection unit 38, the detection-data processing performed by the processing unit 42, and the transmission of the processed data performed by the transmission unit 44. The current detection unit 38, the processing unit 42, the transmission unit 44, and the control unit 46 receive power from the power supply circuit 30 (as indicated by bold arrows).

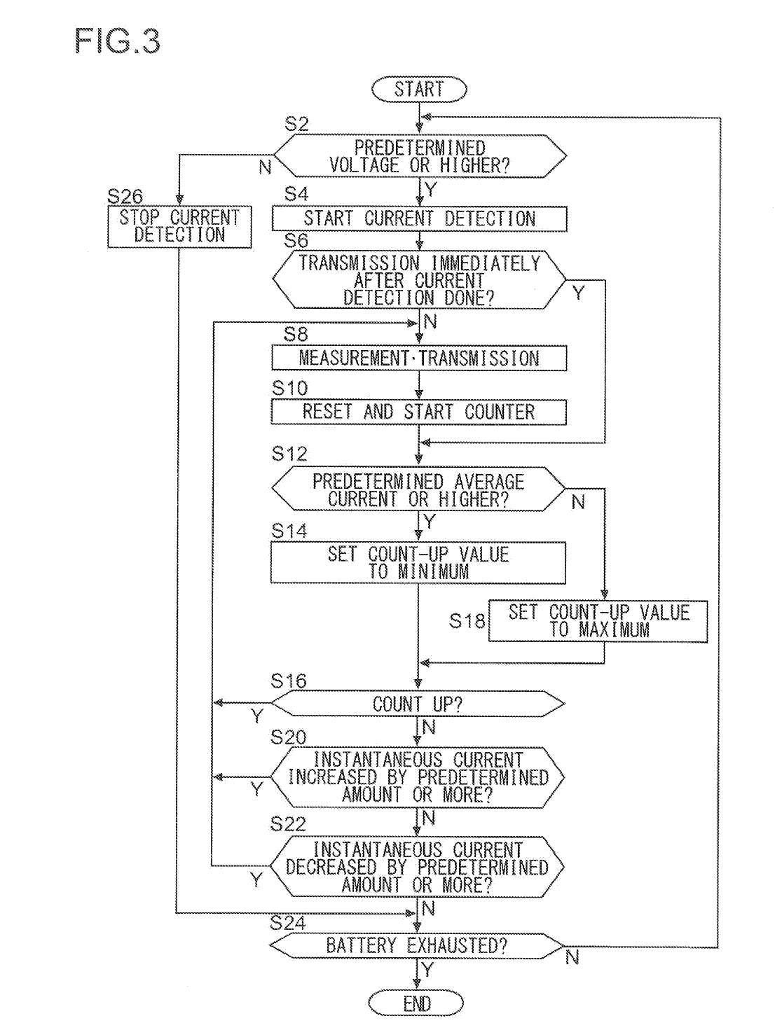

FIG. 3 is a flow chart illustrating an operation of the control unit 46 of the current sensor in Example 1 illustrated in FIG. 2. When current is generated in the coil 26 based on current flowing through the cord 22 and the storage battery 32 is charged to a lowest level sufficient to start up the control unit 46, the control unit 46 is started up and the flow of operation starts. Then in Step S2, it is checked whether or not the storage battery 32 has been charged to a predetermined voltage that is necessary for current detection and transmission of the result of the detection. When the storage battery 32 is found to have been charged to the predetermined voltage or higher, the flow proceeds to step S4, where current detection by the current detection unit 38 is started, and then the flow shifts to step S6. Here, in a case where the current detection has already been started, nothing is done in step S4, and the flow shifts directly to step S6.

In Step S6, it is checked whether or not current measurement and transmission of the result of the current measurement immediately after the start of the current detection in step S4 have been completed, and when not, the flow proceeds to step S8, where the current detection unit 38 and the processing unit 42 perform measurement and the transmission unit 44 performs transmission. Next, a counter for determining a detection interval is reset to start counting in step S10, and the flow reaches step S12. In this way, immediately after the current detection is started, measurement and transmission are each performed once first. On the other hand, when it is found in step S6 that current has been measured and a result of the current measurement has been transmitted immediately after the start of the current detection, no further measurement or transmission is performed and the flow shifts to step S12. Thereafter, measurement and transmission are performed when a condition is satisfied as described later.

Current measurement has been continuously performed by the current detection unit 38 and the processing unit 42 since the start of the current detection, and in step S12, it is checked whether or not a moving average value of the detected current is equal to or larger than a predetermined value. When the moving average value is found to be equal to or larger than the predetermined value, the flow proceeds to step S14, where a count-up value is set to a minimum (two seconds, for example), and the flow shifts to step S16. On the other hand, when the moving average value is found to be smaller than the predetermined value, the flow proceeds to step S18, where the count-up value is set to a maximum (10 seconds, for example), and the flow shifts to step S16. In this manner, when the moving average value of the current detected by the current detection unit 38 is large, then the current flowing through the coil 26 can also be regarded as large, and charging current of the storage battery 32 can also be regarded as large, and thus, the count-up value is reduced to increase the frequency of measurement and transmission, to thereby perform fine measurement and transmission. On the other hand, when the moving average value of the current detected by the current detection unit 38 is small, then the current flowing through the coil 26 can also be regarded as small and the charging current of the storage battery 32 can also be regarded as small, and thus, the count-up value is increased to reduce the frequency of the measurement and the transmission, to thereby reduce consumption of power from the storage battery 32. Here, from step S12 through step S18 in the flow, the count-up value is changed stepwise between two large and small values, but the count-up value may be changed more finely between more than two levels of values, or may be changed substantially non-stepwise and continuously.

In step S16, it is checked whether or not time has been counted up to the set count-up value to complete the counting up. When it is found that the counting up has not yet reached the count-up value (time has not yet been counted up to the count-up value), the flow proceeds to step S20, where it is checked whether or not instantaneous current has been caused to increase by a predetermined amount or more by a sudden increase of the current flowing through the cord 22. When NO in step S20, the flow proceeds to step S22, where it is checked whether or not the instantaneous current has been caused to decrease by a predetermined amount or more by a sudden decrease of the current flowing through the cord 22. When NO in step S22, the flow shifts to step S24. Here, in step S2, when it is found that the storage battery 32 has not yet been charged to the predetermined voltage that is necessary for current detection and transmission of the result of the detection, the flow proceeds to step S26, where the current detection is stopped to reduce power consumption, and then, the flow shifts directly to step S24.

On the other hand, when completion of the counting up is detected in step S16, when increase of the instantaneous current by the predetermined amount or more is detected in step S20, or when decrease of the instantaneous current by the predetermined amount or more is detected in step S22, the flow returns to step S8, where measurement and transmission are performed. Thus, measurement and transmission are basically performed regularly at time intervals based on the set count-up value. Even out of the regular timing, measurement and transmission are immediately performed when increase or decrease of the instantaneous current by the predetermined amount or more has occurred.

In Step S24, it is checked whether or not the storage battery 32 has been exhausted and the control unit 46 should be brought into a standby state. When NO in step S24, the flow returns to step S2, and steps from step S2 through step S26 are repeated until exhaustion of the storage battery 32 is detected in step S24. While the steps are repeatedly performed in this manner, each time it is detected in step S16 that the counting up has reached the count-up value, the flow returns to step S8, and thereby, measurement and transmission are regularly performed. Furthermore, while the steps are repeatedly performed, the measurement and the transmission are extraordinarily performed to deal with changes in the instantaneous current. Here, since steps S20 and S22 are provided, it is possible to deal with peak-like current changes, where current suddenly increases and then suddenly decreases, and measure the behavior of the current, and transmit result of the measurement. On the other hand, when the storage battery is detected to have been exhausted in step S24, the flow is ended, and the control unit 46 enters the standby state.

### EXAMPLE 2

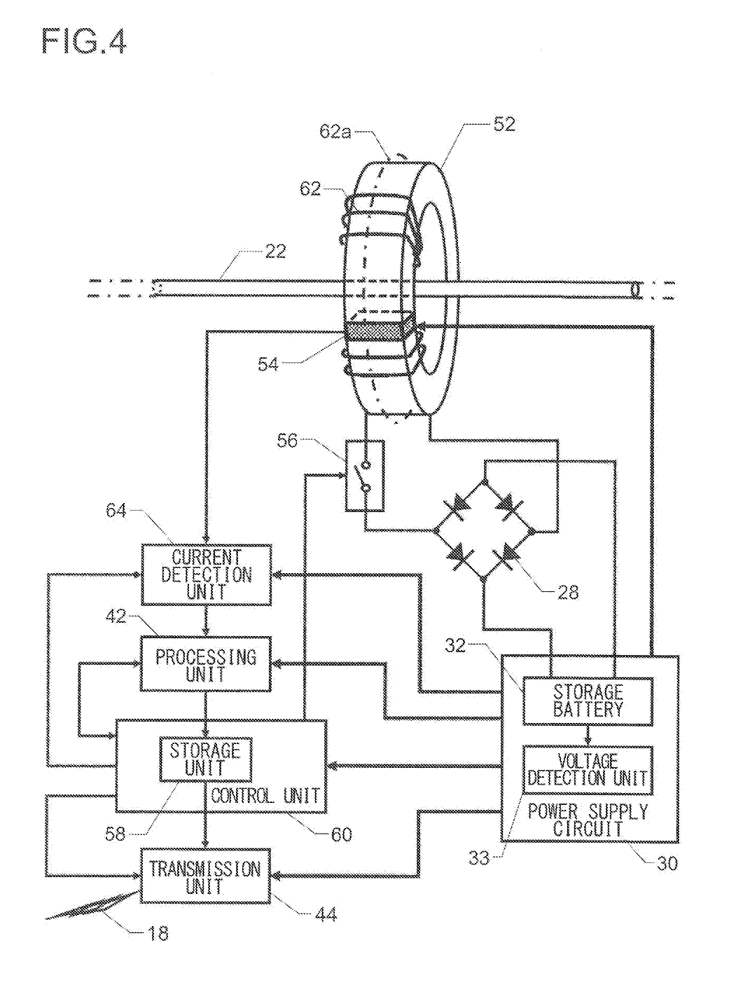

FIG. 4 is partly a conceptual diagram and partly a block diagram of a current sensor in Example 2 of the present invention. Example 2 has the same overall system configuration as Example 1, and the current sensor of Example 2 can be adopted as the first current sensor 10, the second current sensor 12, the third current sensor 14, etc., illustrated in FIG. 1, and thus illustration and description of the entire system of Example 2 will be omitted. Furthermore, the current sensor in Example 2 illustrated in FIG. 4 has many portions in common with the current sensor in Example 1 illustrated in FIG. 2, and thus the same portions as in Example 1 are denoted by the same reference signs, and descriptions thereof will be omitted unless necessary.

The current sensor in Example 2 illustrated in FIG. 4 is different from the current sensor in Example 1 illustrated in FIG. 2 in that an iron core ring 52 is used for both charging and current measurement, that a Hall element 54 is adopted for current measurement, that a switch 56 is provided for avoiding influence of charging on current measurement, and that a storage unit 58 for storing a measured value therein is disposed in a control unit 60 for the purpose of separating timing of measurement from timing of transmission.

Specifically, as in Example 1, in Example 2 as well, the iron core ring 52 having a shape corresponding to magnetic flux generated around one cord 22. Around the iron core ring 52, a coil 62 is wound. (The coil 62 is wound around unillustrated part of the iron-core ring 52, too, as indicated by an alternate dash and dot line 62a.) Also as in Example 1, current extracted from an outgoing wire of the coil 62 charges a storage battery 32 in a power supply circuit 30 via a rectifier 28, but unlike in Example 1, the switch 56 is provided in a charging path, such that the switch 56 remains open while the current measurement is being performed to thereby prevent charging from having an influence on current measurement.

Furthermore, in part of a magnetic circuit that the iron core ring 52 forms, the Hall element 54 is inserted such that the magnetic flux crosses the Hall element 54. Here, the power supply circuit 30 supplies power to the Hall element as well. Magnetic flux density of the iron core ring 52 dependent on the current flowing through the cord 22 is converted into a voltage by the Hall element 54. In this manner, the current flowing through the cord 22 is detected by a current detection unit 64 to which the Hall element is connected. The current detection by the current detection unit 64 is performed also during the charging of the storage battery 32, and is used to measure a moving average current for setting the count-up value and to make a judgement on increase and decrease of the instantaneous current. However, in order to avoid influence of the combined use of the iron core ring 52 on measurement, the control unit 60 opens the switch 56 and suspends charging at the time of measurement.

Furthermore, when the voltage of the storage battery 32 is insufficient to transmit a measured value, the control unit 60 controls such that only the measurement is performed and the measured value is stored in the storage unit 58, and the measured value stored in the storage unit 58 is transmitted when the voltage of the storage battery 32 becomes sufficient for the transmission. For this purpose, the date and time of the measurement is simultaneously stored as a time stamp of the measured value to be stored.

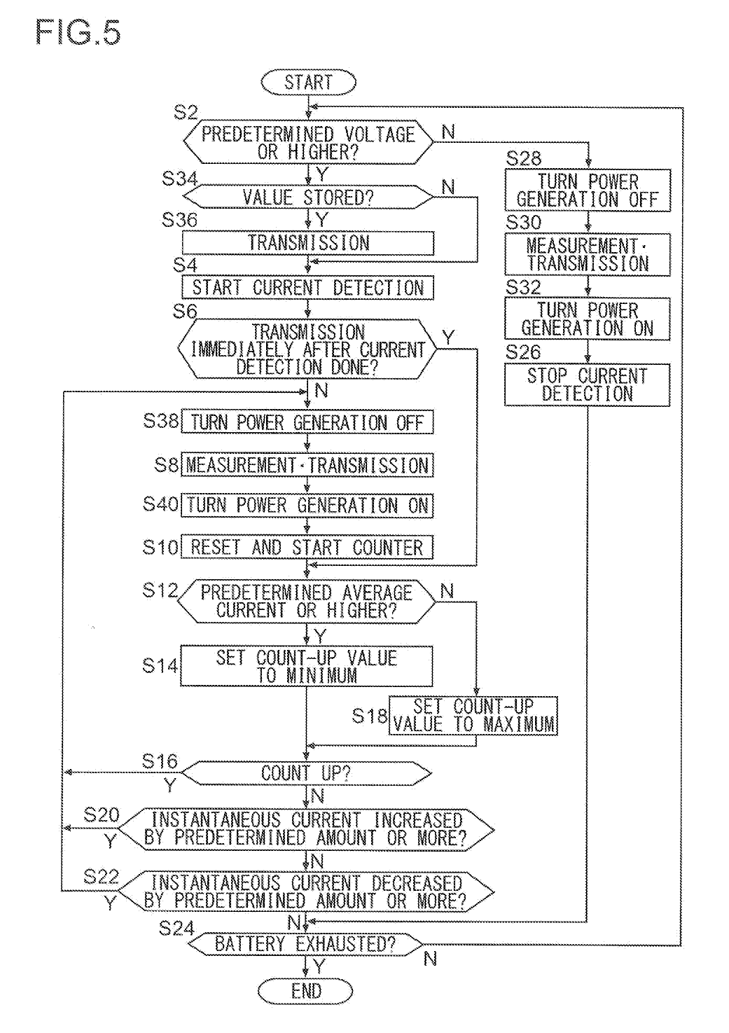

FIG. 5 is a flow chart illustrating an operation of the control unit 60 of the current sensor in Example 2 illustrated in FIG. 4. Furthermore, the flow chart of FIG. 5 has many portions in common with the flow chart of Example 1 illustrated in FIG. 3, and thus the same steps as in the flow chart of Example 1 are denoted by the same step numbers, and descriptions thereof will be omitted unless necessary. Newly added steps in FIG. 5 are indicated by bold letters.

In the flow chart of Example 2 illustrated in FIG. 5, when it is found in step S2 that the storage battery 32 has not yet been charged to the predetermined voltage that is necessary for current detection and transmission of the result of the detection, the flow proceeds to step S28, where the switch 56 is opened to turn power generation off. Then, the flow proceeds to step S30, where measurement by the current detection unit 64 is performed. At this time, since the voltage is insufficient, measurement by the transmission unit 44 is not performed, and the measured value is stored in the storage unit 58. Then, the flow proceeds to step S32, where the switch 56 is closed to turn power generation on. With power generation turned on, the flow proceeds to step S26, where the current detection is stopped, and then, the flow shifts to step S24.

In the flow chart of Example 2 illustrated in FIG. 5, when it is found in step S2 that the storage battery 32 has not yet been charged to the predetermined voltage that is necessary for current detection and transmission of the result of the detection, the flow proceeds to step S34, where it is checked whether or not there is any measured value stored in step S30. When a measured value is found stored, the flow proceeds to step S36, where the stored value is read and transmitted, and then, the flow proceeds to step S4. On the other hand, when no measured value is found stored, the flow proceeds directly to step S4.

Furthermore, in the flow chart of Example 2 illustrated in FIG. 5, when it is found in step S6 that neither current measurement nor transmission immediately after the start of the current detection has not been done yet, the flow proceeds to step S38, where the switch 56 is opened to turn power generation off. With power generation turned off, the flow proceeds to step S8, where measurement by the current detection unit 64 and the processing unit 42 and transmission by the transmission unit 44 are performed. Then, the flow proceeds to step S40, where the switch 56 is closed to turn power generation on. With power generation turned on, the flow proceeds to step S10, where a counter is reset and started. The turning on/off of power generation before/after measurement and transmission as in the flow chart of FIG. 5 is not limited to immediately after the start of current detection as described above; power generation is turned on/off in the same manner, in repetition of the flow, also when it is detected in step S16 that the counting up has reached the count-up value, when increase of the instantaneous current by the predetermined amount or more is detected in step S20, and when decrease of instantaneous current by the predetermined amount or more is detected in step S22. That is, in these cases, too, the flow proceeds, via the turning off of power generation in step S38, to step S8 where measurement and transmission is performed.

### EXAMPLE 3

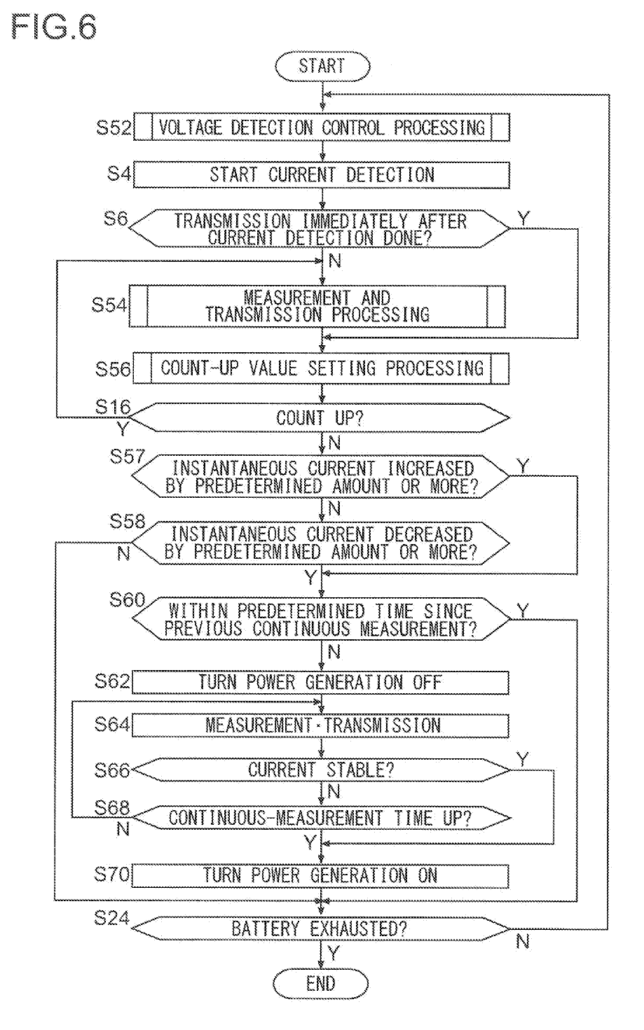

FIG. 6 is a flow chart illustrating an operation of a control unit of a current sensor in Example 3 of a current sensor according to an embodiment of the present invention. The same hardware configuration as in Example 2 illustrated in FIG. 4 is employed in Example 3. The flow chart of FIG. 6 has many portions in common with the flow chart of Example 2 illustrated in FIG. 4, and thus the common portions are illustrated in a packaged-up manner, and the same portions as in the flow chart of Example 2 are denoted by the same step numbers, and descriptions thereof will be omitted unless necessary. Example 3 illustrated in FIG. 6 is different from Example 2 illustrated in FIG. 5 in that Example 3 is configured such that continuous measurement starts to be performed for a predetermined period of time after increase or decrease of instantaneous current by a predetermined amount.

First, a description will be given on such steps in FIG. 5 as are illustrated in packages in FIG. 6. Step S52 in FIG. 6 includes a flow that proceeds from step S2, via step S34, to reach step S36 in FIG. 5, and a flow that proceeds from step S2, via steps S28, S30, S32, and S26, toward step S24 in FIG. 5. Step S54 in FIG. 6 includes a flow that proceeds from step S38, via step S8 and step S40, to reach step S10 in FIG. 5. Step S56 in FIG. 6 includes a flow that proceeds from step S12, via step S14 or step S18, toward step S16 in FIG. 5. These steps are the same as in FIG. 5, and thus their descriptions will be omitted.

In FIG. 6, when the flow reaches step S57, it is checked whether or not the instantaneous current has been caused to increase by the predetermined amount or more by a sudden increase of the current flowing through the cord 22. When NO in step S57, the flow proceeds to step S58, where it is checked whether or not the instantaneous current has been caused to decrease by the predetermined amount or more by a sudden decrease of the current flowing through the cord 22. When YES in step S57 or step S58, the flow proceeds to step S60, where it is checked whether or not time that has elapsed since the previous continuous measurement is within a predetermined period of time. This is to avoid exhaustion of the storage battery 32 due to repetition of continuous measurement in a short period of time. When it is confirmed in step S60 that the time elapsed since the previous continuous measurement is not within the predetermined period of time, the flow proceeds to step S62, where power generation is turned off

Next, the flow proceeds to step S64, where measurement by the current detection unit 64 and the processing unit 42 and transmission by the transmission unit 44 are performed. Then the flow proceeds to step S66, where it is checked whether or not the measurement-target current is stable without large variation. When NO in step S66, the flow proceeds to step S68, where it is checked whether or not time for the continuous measurement is up (lapse of two minutes, for example). When YES in step S68, the flow proceeds to step S70, where the switch 56 is closed to turn power generation on. The flow proceeds to step S70 to turn power generation on also when current stability is confirmed in step S66. These steps in the flow are provided for the purpose of avoiding exhaustion of the storage battery 32 that would result from idle continuation of the continuous measurement. On the other hand, when it is not detected in step S68 that the time for the continuous measurement is up, the flow returns to step S64, and then the process from step S64 through step S68 are repeated such that continuous measurement and transmission are repeatedly performed until current stability is confirmed in step S66 or it is detected in step S68 that the time for the continuous measurement is up. Here, in the case where the flow proceeds to step S70 to turn power generation on as described above, the flow subsequently proceeds to step S24, where the same operation is performed as in the flow of Example 2 illustrated in FIG. 5.

### EXAMPLE 4

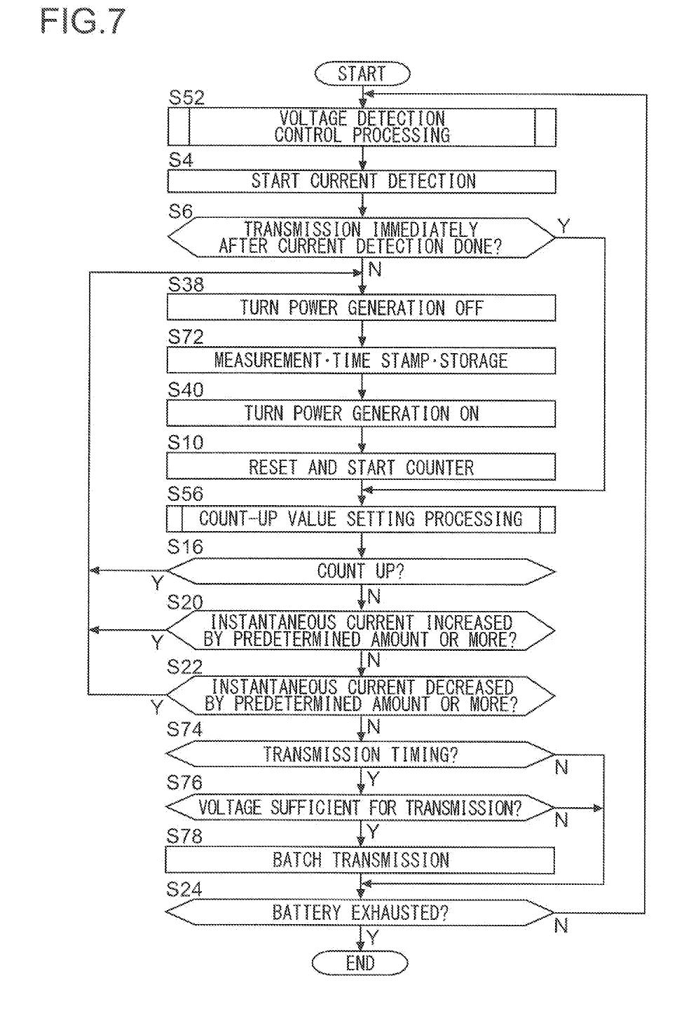

FIG. 7 is a flow chart illustrating an operation of a control unit of a current sensor in Example 4 of a current sensor according to an embodiment of the present invention. The same hardware configuration as in Example 2 illustrated in FIG. 4 is employed in Example 4. The flow chart of FIG. 7 has many portions in common with the flow chart in Example 2 illustrated in FIG. 5, and thus the same steps as in the flow chart of Example 1 are denoted by the same step numbers, and descriptions thereof will be omitted unless necessary. Here, the same way of illustrating a plurality of steps in packages as is adopted in the flow chart of Example 3 illustrated in FIG. 6 is adopted also in part of FIG. 7 with the same step numbers. Example 4 illustrated in FIG. 7 is different from Example 2 illustrated in FIG. 5 in that measurement and transmission are completely separated from each other in such a manner that measured values are stored and accumulated in a predetermined period of time and then the stored and accumulated values are transmitted in a batch at a predetermined transmission timing. Here, in FIG. 7 illustrating Example 4, changed or newly added steps in comparison with FIG. 5 illustrating Example 2 are indicated by bold letters.

In the example illustrated in FIG. 7, after power generation is turned off in step S38, current measurement is performed by the current detection unit 64 and the processing unit 42 and the measured value is stored in the storage unit 58. At this time, the date and time of the measurement is simultaneously stored as a time stamp. Transmission is not performed at this stage, and the flow shifts to step S40, where power generation is turned on.

In the example illustrated in FIG. 7, when it is not detected in step S22 that the instantaneous current has decreased by a predetermined amount or more, the flow shifts to step S74, where it is checked whether or not the predetermined transmission timing (for example, every one minute) has been reached. When the transmission timing is found to have been reached, the flow shifts to step S76, where it is checked whether or not the storage battery 32 has a voltage sufficient for transmission. When the voltage of the storage battery 32 is found to be sufficient, the flow proceeds to step S78, where the measured values stored in the storage unit 58 are transmitted in a batch, and then the flow proceeds to step S24. On the other hand, when it is not confirmed that the predetermined transmission timing has been reached, or, when it is not able to confirm that the voltage of the storage battery 32 is sufficient for transmission, the batch transmission of the stored measured values is postponed until the next opportunity and the flow shifts directly to step S24. The operation after the flow proceeds to step S24 is the same as in the flow of Example 2 illustrated in FIG. 5.

### EXAMPLE 5

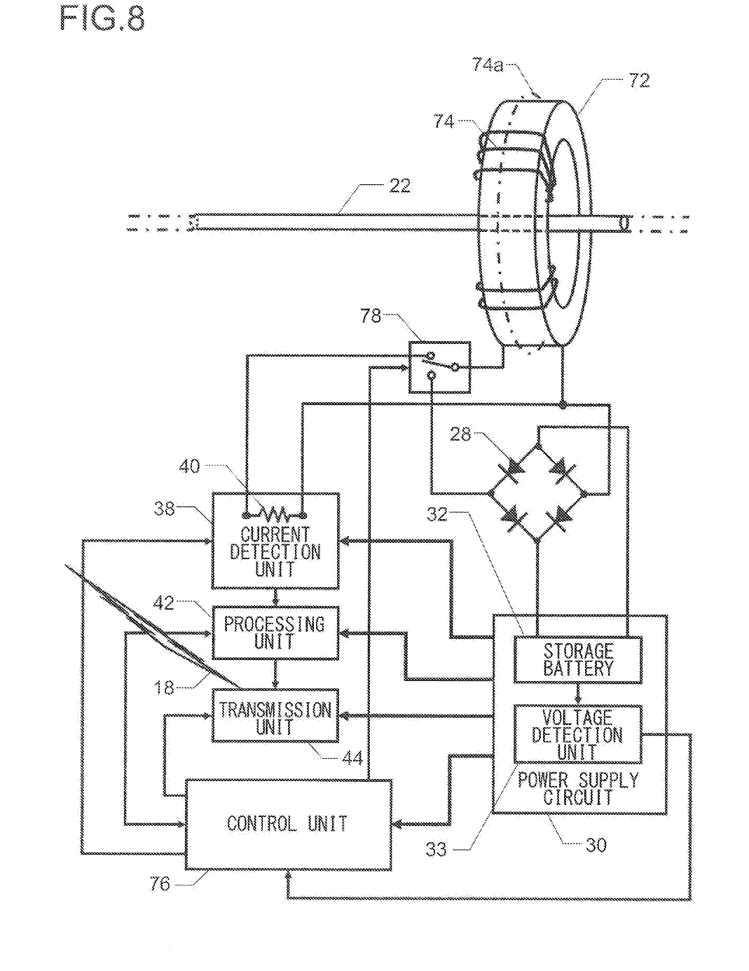

FIG. 8 is partly a conceptual diagram and partly a block diagram of a current sensor in Example 5 of the current sensor according to an/the embodiment of the present invention. Example 5 has the same overall system configuration as Example 1, and the current sensor of Example 5 can be adopted as the first current sensor 10, the second current sensor 12, the third current sensor 14, etc. illustrated in FIG. 1, and thus illustration and description of the entire system configuration of Example 5 will be omitted. Furthermore, the current sensor in Example 5 has many portions in common with the current sensor in Example 1 illustrated in FIG. 2, and thus the same portions as in Example 1 are denoted by the same reference signs, and descriptions thereof will be omitted unless necessary.

The current sensor in Example 5 illustrated in FIG. 8 is different from the current sensor in Example 1 illustrated in FIG. 1 in that an iron core ring 72 and a coil 74 wound around the iron core ring 72 (which is wound around unillustrated part of the iron-core ring 72, too, as indicated by an alternate dash and dot line 74a) are used both for charging and current measurement, and also in that time division between measurement time and charging time is achieved by using a switch 78 that is controlled by a control unit 76 to switch the connection destination of an outgoing wire of the coil 74.

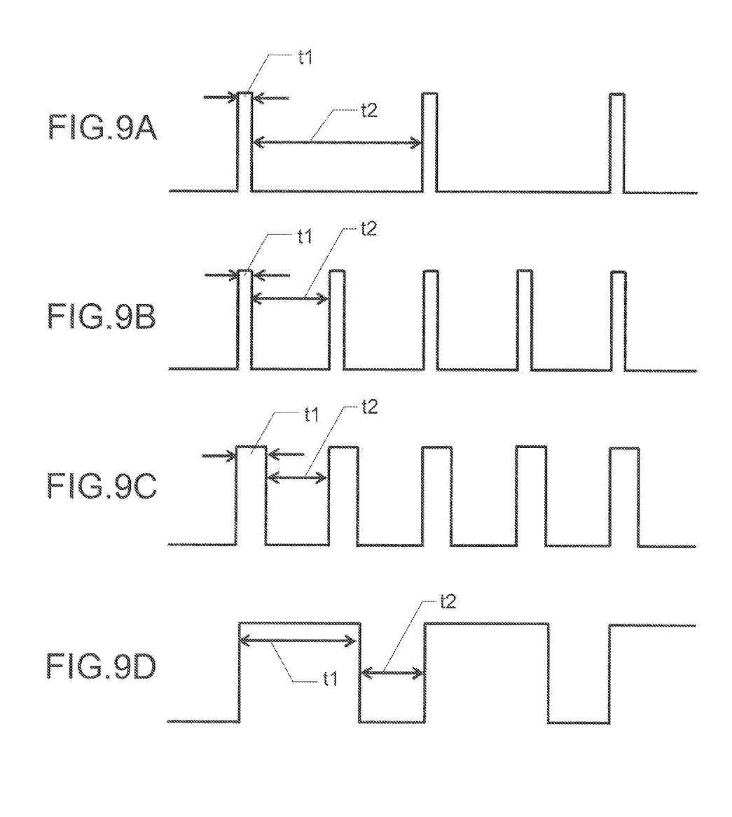

FIG. 9A to FIG. 9D are each a diagram illustrating timing of an operation of the control unit 76 in Example 5 illustrated in FIG. 8. FIG. 9A illustrates a case where the remaining capacity of the storage battery 32 is small and charging current caused by the current flowing through the cord 22 is also small, and the relative magnitude of the duty of the measurement time t1 with respect to the duty of the charging time t2 is smaller than in FIGS. 9B, 9C, and 9D. That is, in FIG. 9A, the width and the frequency of the measurement time tl are both smaller than in FIGS. 9B, 9C, and 9D.

In contrast to FIG. 9A, FIG. 9B illustrates a case where there is a little margin in the remaining capacity of the storage battery 32 and the magnitude of the charging current, and the width of the measurement time t1 remains the same as in the case of FIG. 9A, but the frequency is twice as large. FIG. 9C illustrates a case where there is a larger margin in the remaining capacity of the storage battery 32 and the magnitude of the charging current than in FIG. 9B, and the frequency of the measurement time t1 remains the same as in the case of FIG. 9B, but the width of the measurement time t1 is larger than in the case of FIG. 9B. Thus, it is also possible to perform continuous measurement within the measurement time t1. FIG. 9D illustrates a case where there is the largest margin in the remaining capacity of the storage battery 32 and the magnitude of the charging current, and the width of the measurement time t1 is larger than that of the charging time t2. The control of these cases is performed based on a judgment made by the control unit 76, and the judgment is made based on the voltage of the voltage detection unit 33 and the magnitude of current measured in current measurement.

The various features dealt with in the descriptions of the examples of the present invention are not necessarily unique to the respective examples, and as along as it is possible to make use of the advantages of the features of the examples, the features can be utilized by being appropriately replaced or combined with each other. For example, the current sensor of Example 1 illustrated in FIG. 2 may be such a Hall element as in Example 2. Furthermore, in the continuous measurement in Example 3 illustrated in FIG. 6, measurement and transmission may be completely separated from each other as in Example 4 illustrated in FIG. 7 such that only the measurement is continuously performed and the transmission is performed in a batch manner at each predetermined timing.

Moreover, in Example 5 illustrated in FIG. 8, measurement and transmission may further be separated from each other within the measurement time t1 such that the transmission is performed in a batch manner as in Example 4 illustrated in FIG. 7. In this case, in the state where the width and the frequency of the measurement time t1 are made minimum as in FIG. 9A, a larger number of cases may be assumed including a case where only the measurement is performed without performing the transmission when the charging current is even smaller.

### INDUSTRIAL APPLICABILITY

The present invention is applicable to a current sensor.

### LIST OF REFERENCE SIGNS

22 target electrical wire
34, 36, 54, 72, 74 measurement unit
44 radio communication unit
24, 26, 52, 62 power generation unit
32 storage battery
46, 60, 76 control section
58 storage unit
52, 72 common iron core

1. Current sensor comprising:
a measurement unit that measures current flowing through a target electrical wire that is a target of measurement;
a wireless transmission unit that wirelessly transmits a result of measurement performed by the measurement unit;
a power generation unit that generates power by means of electromagnetic induction caused by magnetic flux around the target electrical wire; and
a storage battery that is charged by the power generation unit and supplies power to the measurement unit and the wireless transmission unit.

2. The current sensor according to claim 1 further comprising
a control unit that performs control such that the measurement unit performs measurement by means of change in the current flowing through the target electrical wire.

3. The current sensor according to claim 2
wherein the control unit performs control such that the measurement unit performs measurement by means of a sudden change in the current flowing through the target electrical wire.

4. The current sensor according to claim 2,
wherein the control unit also performs control such that the measurement unit performs measurement at predetermined time intervals.

5. The current sensor according to claim 1 further comprising
a control unit that controls, by means of magnitude of the current flowing through the target electrical wire, timing for the wireless transmission unit to perform transmission.

6. The current sensor according to claim 1 further comprising
a control unit that makes the power generation unit stop power generation when the measurement unit performs measurement.

7. The current sensor according to claim 1 further comprising
a control unit that keeps the measurement unit from performing measurement when the control unit makes the power generation unit perform power generation.

8. The current sensor according to claim 1 further comprising
a storage unit in which the result of measurement performed by the measurement unit is stored; and
a control unit that stores and maintains the result of measurement in the storage unit, and that makes the wireless transmission unit transmit the result of measurement stored in the storage unit at timing different from timing of measurement.

9. The current sensor according to claim 8,
wherein
the control unit stores and maintains the result of measurement in the storage unit when supply of power from the storage battery to the wireless transmission unit is insufficient, and
when sufficient power supply is secured from the storage battery to the wireless transmission unit, the control unit makes the wireless transmission unit transmit the result of measurement stored in the storage unit.

10. The current sensor according to claim 1,
wherein the measurement unit is used both for measuring the current flowing through the target electrical wire and for measuring charging current with which the storage battery is charged by the power generation unit.

11. The current sensor according to claim 1,
wherein
the measurement unit measures the current flowing through the target electrical wire by means of the electromagnetic induction caused by the magnetic flux around the target electrical wire, and
a common iron core through which the magnetic flux passes is shared by the measuring unit and the power generation unit.

12. A current sensor comprising:
a measurement unit that measures current flowing through a target electrical wire that is a target of measurement;
a power generation unit that generates power by means of electromagnetic induction caused by magnetic flux around the target electrical wire; and
a storage battery that is charged by the power generation unit and supplies power to the measurement unit,
wherein
the measurement unit is used both for measuring the current flowing through the target electrical wire and for measuring charging current with which the storage battery is charged by the power generation unit.

13. The current sensor according to claim 12 further comprising
a control unit that performs control such that the measurement unit performs measurement by means of change in the current flowing through the target electrical wire.

14. The current sensor according to claim 13,
wherein the control unit also performs control such that the measurement unit performs measurement at predetermined time intervals.

15. The current sensor according to claim 12 further comprising
a control unit that makes the power generation unit stop power generation when the measurement unit performs measurement.

16. The current sensor according to claim 12 further comprising
a control unit that keeps the measurement unit from performing measurement when the control unit makes the power generation unit perform power generation.

17. A current sensor comprising:
a measurement unit that measures current flowing through a target electrical wire that is a target of measurement by means of electromagnetic induction caused by magnetic flux around the target electrical wire;
a power generation unit that generates power by means of the electromagnetic induction caused by the magnetic flux around the target electrical wire; and
a storage battery that is charged by the power generation unit and supplies power to the measurement unit,
wherein
a common iron core through which the magnetic flux passes is shared by the measurement unit and the power generation unit.

18. The current sensor according to claim 17 further comprising
a control unit that performs control such that the measurement unit performs measurement by means of change in the current flowing through the target electrical wire.

19. The current sensor according to claim 17 further comprising
a control unit that makes the power generation unit stop power generation when the measurement unit performs measurement.

20. The current sensor according to claim 17 further comprising
a control unit that keeps the measurement unit from performing measurement when the control unit makes the power generation unit perform power generation.
